(19) United States
(12) Patent Application Publication
(10) Pub. No.: US 2020/0172666 A1
(43) Pub. Date: Jun. 4, 2020

(54) THERMOSETTING RESIN COMPOSITION, THERMOSETTING SHEET, SEMICONDUCTOR COMPONENT, AND SEMICONDUCTOR MOUNTED ARTICLE

(71) Applicant: PANASONIC INTELLECTUAL PROPERTY MANAGEMENT CO., LTD., Osaka (JP)

(72) Inventors: Yasuo FUKUHARA, Osaka (JP); Atsushi YAMAGUCHI, Osaka (JP)

(73) Assignee: PANASONIC INTELLECTUAL PROPERTY MANAGEMENT CO., LTD., Osaka (JP)

(21) Appl. No.: 16/615,343

(22) PCT Filed: Jun. 9, 2017
(86) PCT No.: PCT/JP2017/021463

§ 371 Date: Nov. 20, 2019

(30) Foreign Application Priority Data
May 22, 2017 (JP) 2017-101054

(51) Int. Cl. C08G 65/18; C08K 5/35; C08K 5/11; C08K 5/17; C08K 5/41; C08L 63/00; C08G 59/50; H01L 23/00

(52) U.S. Cl. CPC C08G 65/18; C08K 5/35; C08K 5/11; C08K 5/17; C08K 5/41; H01L 2224/29007; C08G 59/5046; H01L 24/15; H01L 24/81; H01L 24/31; C08L 63/00

(57) ABSTRACT

A thermosetting resin composition contains a thermosetting resin, an activator, and a thixotropy-imparting agent. The thermosetting resin contains a main agent and a curing agent. The main agent contains a di- or higher functional oxetane compound.

### TECHNICAL FIELD

The present invention relates to a thermosetting resin composition used to mount an electronic component on a substrate, a thermosetting sheet, a semiconductor component, a semiconductor mounted article, a method for producing the semiconductor component, and a method for producing the semiconductor mounted article.

### BACKGROUND ART

A method is known which adopts, to mount a semiconductor component on a circuit board, a thermosetting resin composition containing solder particles (e.g., see Patent Literature 1). In this method, a resin cured portion covers around a solder part where the solder particles melted and aggregated. This improves drop impact resistance of a packaging structure of the semiconductor component.

A paste-like thermosetting resin composition containing solder particles, however, has, for example, the following problem. That is, during soldering, the solder particles are melted, and solder pieces are aggregated (metallized). When solder particles, such as Sn—Ag—Cu-based solder particles, having a relatively high melting point are adopted, adopting a thermosetting resin, such as a typical epoxy resin, results in that the thermosetting resin inhibits aggregation of the solder pieces. If self-aggregation of the solder particles is inhibited as is the case with the typical epoxy resin, electrical conduction failure occurs.

One of the causes of the above-described problem is, for example, that curing speed of the thermosetting resin is too high as compared to the speed of aggregation of the solder pieces thus melted. In this case, a curing reaction of the thermosetting resin can end faster than melting and subsequent self-aggregation of the solder particles. Therefore, a cured product of the thermosetting resin may be formed as an insulator between the solder particles.

Another cause for inhibition of the self-aggregation of the solder particles is, for example, that the thermosetting resin has a curing start temperature which is too low as compared to the melting point of the solder particles. In this case, heating during the soldering may result in that the curing start temperature of the thermosetting resin is reached at first, and the melting temperature of the solder powder is then reached. Thus, before the solder particles are melted, the thermosetting resin starts curing, which may form an electrical insulator between the solder particles.

It is difficult for existing techniques to reduce the curing speed of the thermosetting resin and/or to increase the curing start temperature of the thermosetting resin.

It is an object of the present disclosure to provide: a thermosetting resin composition which is suppressed from curing before melting of solder during soldering and which is configured to reinforce a solder bonding part formed after the soldering; a thermosetting sheet; a semiconductor component; a semiconductor mounted article; a method for producing the semiconductor component; and a method for producing the semiconductor mounted article.

### CITATION LIST

### Patent Literature

Patent Literature 1: JP 2011-176050 A

### SUMMARY OF INVENTION

A thermosetting resin composition according to a first aspect of the present invention includes a thermosetting resin, an activator, and a thixotropy-imparting agent. The thermosetting resin contains a main agent and a curing agent. The main agent contains a di- or higher functional oxetane compound.

A thermosetting resin composition according to a second aspect of the present invention includes a thermosetting resin, an activator, and a thixotropy-imparting agent. The thermosetting resin contains a main agent and a curing agent. The curing agent contains a benzoxazine compound having two or more benzoxazine rings.

A thermosetting sheet according to the present invention is formed from a semi-cured product of the thermosetting resin composition according to the first or second aspect.

A semiconductor component according to the present invention includes: a semiconductor package; a first substrate having a first surface and a first pad formed on the first surface; a first solder bonding part which electrically connects the semiconductor package to the first pad; and a first resin part in contact with the first solder bonding part. The first resin part is formed from a cured product of a thermosetting resin composition containing at least one of a di- or higher functional oxetane compound or a benzoxazine compound having two or more oxazine rings.

A semiconductor mounted article according to the present invention includes: a semiconductor package; a first substrate having a first surface and a second surface on an opposite side from the first surface, the first substrate having a first pad formed on the first surface and a land formed on the second surface; a first solder bonding part which electrically connects the semiconductor package to the first pad; a first resin part in contact with the first solder bonding part; a second substrate having a first surface and a second pad formed on the first surface; a second solder bonding part which electrically connects the land to the second pad; and a second resin part in contact with the second solder bonding part. The first resin part is formed from a cured product of a first thermosetting resin composition containing at least one of a di- or higher functional oxetane compound or a benzoxazine compound having two or more oxazine rings. The second resin part is formed from a cured product of a second thermosetting resin composition containing at least one of a di- or higher functional oxetane compound or a benzoxazine compound having two or more oxazine rings.

A method for producing a semiconductor component according to the present invention includes the following step A1 to step D1.

Step A1 is a step of preparing: a semiconductor package provided with a first solder bump; and a first substrate having a first surface and a first pad formed on the first surface.

Step B1 is a step of applying or disposing a first thermosetting resin composition to or on the first surface of the first substrate. The first thermosetting resin composition contains: at least one of a di- or higher functional oxetane compound or a benzoxazine compound having two or more oxazine rings; an activator; and a thixotropy-imparting agent.

Step C1 is a step of disposing the first solder bump on the first pad.

Step D1 is a step of performing reflow soldering by heating the semiconductor package and the first substrate for four minutes or longer such that a peak temperature is higher than or equal to 220° C. and lower than or equal to 260° C.

A method for producing a semiconductor mounted article according to the present invention includes steps A2 to 12 below.

Step A2 is a step of preparing a semiconductor package and a first substrate. The semiconductor package is provided with a first solder bump. The first substrate has a first surface and a second surface on an opposite side from the first surface. The first substrate has a first pad formed on the first surface and a land formed on the second surface.

Step B2 is a step of applying or disposing a first thermosetting resin composition to or on the first surface of the first substrate, the first thermosetting resin composition containing: at least one of a di- or higher functional oxetane compound or a benzoxazine compound having two or more oxazine rings; an activator; and a thixotropy-imparting agent.

Step C2 is a step of disposing the first solder bump on the first pad.

Step D2 is a step of performing reflow soldering by heating the semiconductor package and the first substrate for four minutes or longer such that a peak temperature is higher than or equal to 220° C. and lower than or equal to 260° C.

Step E2 is a step of forming a second solder bump on the land.

Step F2 is a step of a second substrate having a first surface and a second pad formed on the first surface is prepared.

Step G2 is a step of applying a second thermosetting resin composition to or disposed on the first surface of the second substrate, the first thermosetting resin composition containing: at least one of a di- or higher functional oxetane compound or a benzoxazine compound having two or more oxazine rings; an activator; and a thixotropy-imparting agent.

Step H2 is a step of disposing the second solder bump on the second pad.

Step I2 is a step of performing reflow soldering by heating the semiconductor package, the first substrate, and the second substrate for four minutes or longer such that a peak temperature is higher than or equal to 220° C. and lower than or equal to 260° C.

### Advantageous Effects of Invention

According to the present invention, a thermosetting resin composition is suppressed from curing before melting of solder during soldering and is configured to reinforce a solder bonding part formed after the soldering.

### BRIEF DESCRIPTION OF DRAWINGS

FIG. 1 is a schematic sectional view illustrating a semiconductor component according to a fourth embodiment of the present invention;

FIG. 2A is a schematic sectional view illustrating part of the semiconductor component;

FIG. 2B is a schematic sectional view illustrating another part of the semiconductor component;

FIG. 3 is a schematic sectional view illustrating step A1 in a method for producing the semiconductor component;

FIG. 4A is a schematic sectional view illustrating step B1-1 in the method for producing the semiconductor component;

FIG. 4B is a schematic sectional view illustrating step C1 in the method for producing the semiconductor component;

FIG. 5A is a schematic sectional view illustrating an example of step B1-2 in the method for producing the semiconductor component;

FIG. 5B is a schematic sectional view illustrating step C1 in the method for producing the semiconductor component;

FIG. 6A is a schematic sectional view illustrating another example of step B1-2 in the method for producing the semiconductor component;

FIG. 6B is a schematic sectional view illustrating step C1 in the method for producing the semiconductor component;

FIG. 7 is a schematic sectional view illustrating a semiconductor mounted article according to a fifth embodiment of the present invention;

FIG. 8A is a schematic sectional view illustrating step G2-1 in a method for producing the semiconductor mounted article;

FIG. 8B is a schematic sectional view illustrating step H2 in the method for producing the semiconductor mounted article;

FIG. 9A is a schematic sectional view illustrating an example of step G2-2 in the method for producing the semiconductor mounted article;

FIG. 9B is a schematic sectional view illustrating step H2 after step G2-2 in the method for producing semiconductor mounted article;

FIG. 10A is a schematic sectional view illustrating another example of step G2-2 in the method for producing the semiconductor mounted article; and

FIG. 10B is a schematic sectional view illustrating step H2 after step G2-2 of FIG. 10A in the method for producing semiconductor mounted article.

### DESCRIPTION OF EMBODIMENTS

Embodiments of the present invention will be described below.

### First Embodiment

[Thermosetting Resin Composition]

A thermosetting resin composition according to a first embodiment contains a thermosetting resin, an activator, and a thixotropy-imparting agent. These components included in the thermosetting resin composition will be described below.

(Thermosetting Resin)

The thermosetting resin is a main material for forming a first resin part 51 and a second resin part 52 which will be described later. The thermosetting resin contains a main agent and a curing agent. The main agent and the curing agent will be described below.

<Main Agent>

The main agent contains a di- or higher functional oxetane compound. The di- or higher functional oxetane compound is a compound having two or more oxetane rings. The oxetane ring is a saturated four-membered ring including one oxygen atom. In the following description, unless otherwise specifically indicated, the simple term “oxetane compound” means a di- or higher functional oxetane compound. A curing reaction proceeds due to ring-opening and cross-linkage of the four-membered ring of the oxetane compound. Since the speed of the ring-opening of the four-membered ring is lower than the speed of the ring-opening of a three-membered ring, a main agent having the four-membered ring reduces the speed of the curing reaction more than a main agent having the three-membered ring. Specifically, typical examples of a compound having the three-membered ring include an epoxy compound. The curing speed of the thermosetting resin can be reduced more by adopting the oxetane compound as the main agent than by adopting the epoxy compound as the main agent. Thus, reducing the curing speed enables the thermosetting resin composition to be suppressed from curing before melting of solder during soldering.

Here, the solder includes solder for forming first solder bumps 6 which will be described later and solder for forming second solder bumps 8 which will be described later. Also in the following description, unless otherwise specifically indicated, “solder” has a similar meaning to the above-defined meaning.

The soldering includes: heating and melting the first solder bumps 6 which will be described later so as to form first solder bonding parts 41; and heating and melting the second solder bumps 8 which will be described later so as to form second solder bonding parts 42.

The oxetane compound may be in liquid form or solid at an ordinary temperature (e.g., higher than or equal to 20° C. and lower than or equal to 40° C.). Note that the main agent may contain a mono-functional oxetane compound having only one oxetane ring.

The oxetane compound is preferably one or more types of compounds selected from the group consisting of formulae (O1) to (O4) below.

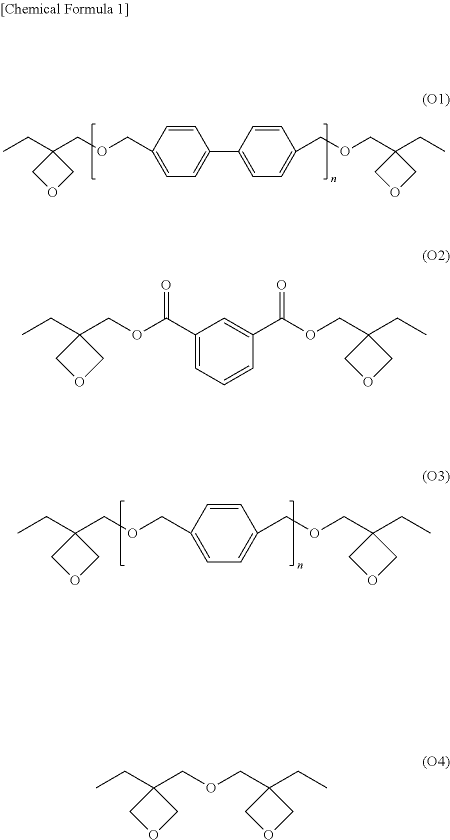

(In each of the formulae (O1) and (O3), n is an integer of any of 1 to 3.)

The oxetane compound represented by the formula (O1) is 4,4′-bis[(3-ethyl-3-oxetanyl)methoxymethyl]biphenyl. The oxetane compound represented by the formula (O1) has a structure (biphenyl skeleton) in which two benzene rings are connected by a single bond, and this biphenyl skeleton is similar to a basic skeleton of bisphenols. Therefore, the oxetane compound represented by the formula (O1) has satisfactory compatibility with epoxy compounds such as bisphenol F.

The oxetane compound represented by the formula (O2) is bis[(3-ethyloxetane-3-yl)methyl]benzene-1,3-dicarboxylate

The oxetane compound represented by the formula (O3) is xylylene bisoxetane.

The oxetane compound represented by the formula (O4) is 3-ethyl-3 [(3-ethyloxetane-3-yl)methoxy]methyloxetane.

The oxetane compound is preferably 50% by mass or more and may be 100% by mass relative to the total mass of the main agent. Even when the main agent contains components other than the oxetane compound, the oxetane compound accounting for 50% by mass or more reduces the influence of the components other than the oxetane compound. This enables the curing speed of the thermosetting resin to be reduced.

The main agent preferably further contains a di- or higher functional epoxy compound. The di- or higher functional epoxy compound is a compound having two or more epoxy groups. The epoxy group is oxacyclopropane (oxirane) which is ether with a three-membered ring. In the following description, unless otherwise specifically indicated, the simple term “epoxy compound” means a di- or higher functional epoxy compound. As described above, in the course of the curing reaction, the ring-opening speed of the four-membered ring of the oxetane compound is low, whereas the ring-opening speed of the three-membered ring of the epoxy compound is high. Thus, when both the oxetane compound and the epoxy compound are adopted in combination with their amounts being adjusted, curing of the thermosetting resin is adjustable to be accelerated or decelerated. Moreover, when the epoxy compound is contained, eventually reducing the formation of an uncured portion of the thermosetting resin to increase the strength of a cured product is also possible. When the oxetane compound and the epoxy compound are used in combination, the structures of the oxetane compound and the epoxy compound are preferably similar to each other in order to increase the compatibility. For example, the oxetane compound having the biphenyl skeleton as described above has satisfactory compatibility with the epoxy compound such as bisphenol F.

<Curing Agent>

In the first embodiment, the curing agent is, but not particularly limited to, the curing agent preferably contains a benzoxazine compound including two or more oxazine rings. The benzoxazine compound will be described in detail in a second embodiment.

(Activator)

The activator is also referred to as a flux. The activator is a solvent for: removing an oxide film covering a surface of solder; reducing oxidation; and reducing surface tension to enhance wettability. The activator is not particularly limited as long as it has such functions. The activator preferably contains one or more types of compounds selected from the group consisting of a glutaric acid and triethanolamine. More preferably, in terms of the synergetic effect, the activator contains both a glutaric acid and triethanolamine. In this case, the glutaric acid mainly has a function of removing the oxide film on the surface of the solder, and the triethanolamine acts to maintain the function. These activators do not decompose and are stable even when the solder has a melting point of 240° C. Thus, the activators can maintain the effect also at such a high temperature. Further, these activators are less likely to remain as a modified product (flux residue) after soldering and are also effective to reduce the viscosity of the thermosetting resin composition.

(Thixotropy-Imparting Agent)

The thixotropy-imparting agent is an additive that imparts thixotropy to the thermosetting resin composition. The thixotropy is one of properties that is important during application (e.g., printing) of, in particular, a thermosetting resin composition in liquid form. Imparting the thixotropy to the thermosetting resin composition enables a reduction of stringing generated when a screen plate is separated from a print surface after performing, for example, screen printing for printing. The thixotropy-imparting agent is not particularly limited. Preferably, the thixotropy-imparting agent contains amide-based wax. Specific examples of the amide-based wax include N-hydroxyethyl-12-hydroxystearylamide.

(Others)

The thermosetting resin composition substantially contains no conductor such as solder powder. Thus, the thermosetting resin composition has an electric insulation property before and after curing.

The thermosetting resin, the activator, and the thixotropy-imparting agent preferably have compatibility with one another. Thus, it becomes easy to impart thixotropy to the thermosetting resin composition.

The thermosetting resin composition preferably contains substantially no rubber powder. The rubber powder has not very high compatibility with each of the thermosetting resin, the activator, and the thixotropy-imparting agent. Thus, when the thermosetting resin composition contains substantially no rubber powder, degradation of thixotropy can be reduced.

The thermosetting resin composition preferably contains substantially no inorganic filler such as silica. Thus, at the time of soldering which will be described later, it is possible to repress inhibition of coupling between each first solder bump 6 and a corresponding one of first pads 21 and coupling between each second solder bump 8 and a corresponding one of second pads 22 due to the inorganic filler.

The thermosetting resin composition preferably contains substantially no volatile organic compound. Thus, it is possible to reduce degradation of the conduction reliability of first solder bonding parts 41 and second solder bonding parts 42 which will be described later. It is also possible to reduce the formation of voids in the first resin part 51 and the second resin part 52 which will be described later. Specific examples of the volatile organic compound include dihydric alcohol (glycol), polyhydric alcohol, glycol ester, and glycol ether.

The thermosetting resin composition preferably contains substantially no curing accelerator such as 2-phenyl-4,5-dihydroxymethylimidazole, 2,4-diamino-6-[2 ‘-methylimidazolyl-(1’)]-ethyl-s-triazine/isocyanuric acid adduct, 1-cyanoethyl-2-phenylimidazole, 2-phenyl-4-methyl-5-hydroxymethylimidazole. Thus, it is possible to suppress the curing reaction of the thermosetting resin from rapidly proceeding.

[Method for Producing Thermosetting Resin Composition]

The thermosetting resin composition according to the first embodiment may be produced as described below.

First, a thixotropy-imparting agent, an oxetane compound as a main agent, and other main agents (e.g., an epoxy compound) as necessary are blended together and are heated to melt the thixotropy-imparting agent, thereby obtaining a first mixture.

Then, with the first mixture, an activator and a curing agent (e.g., a benzoxazine compound) are blended to obtain a mixture, which is kneaded with a kneader such as a planetary mixer, thereby obtaining a thermosetting resin composition. The activator and the curing agent used, if being solids, are preferably those sieved through, for example, a plain weave mesh screen having an opening of 125 μm and a wire diameter of 90 μm according to JIS Z 8801 for the purpose of uniform dispersion.

The thermosetting resin composition according to the first embodiment may be an uncured A-stage product (in liquid form) or a semi-cured B-stage product. “A stage” means a stage before starting of the curing reaction. Heating the uncured A-stage product results in the semi-cured B-stage product. “B stage” means an intermediate stage of the curing reaction. When the semi-cured B-stage product is further heated, the semi-cured product is once melted and then results in a cured C-stage product (solid). “C stage” means a stage after full curing. Thus, B stage means a stage between A stage and C stage.

### Second Embodiment

[Thermosetting Resin Composition]

A thermosetting resin composition according to a second embodiment contains a thermosetting resin, an activator, and a thixotropy-imparting agent. The activator and the thixotropy-imparting agent are similar to those in the first embodiment, and the description thereof is thus omitted. The thermosetting resin will be described below. Note that the matters described in (Others) in the first embodiment are applicable to the second embodiment.

(Thermosetting Resin)

The thermosetting resin contains a main agent and a curing agent. The main agent and the curing agent will be described below.

<Main Agent>

In the second embodiment, the main agent is not particularly limited but preferably contains a di- or higher functional oxetane compound. The oxetane compound is the same as that described in the first embodiment.

The main agent preferably further contains a di- or higher functional epoxy compound. The epoxy compound is the same as that described in the first embodiment.

<Curing Agent>

The curing agent preferably contains a benzoxazine compound including two or more oxazine rings. The oxazine ring is a hetero ring with a six-membered ring containing one oxygen atom and one nitrogen atom as shown on the left of the arrow in the following formula (B0). In the following description, unless otherwise specifically indicated, the simple term “benzoxazine compound” means a benzoxazine compound having two or more oxazine rings. As shown in the following formula (B0), when the benzoxazine compound is heated to approximately 200° C., an —O—CH₂— bond of the oxazine ring is broken to cause a ring-opening, thereby generating a phenolic hydroxy group and tertiary amine.

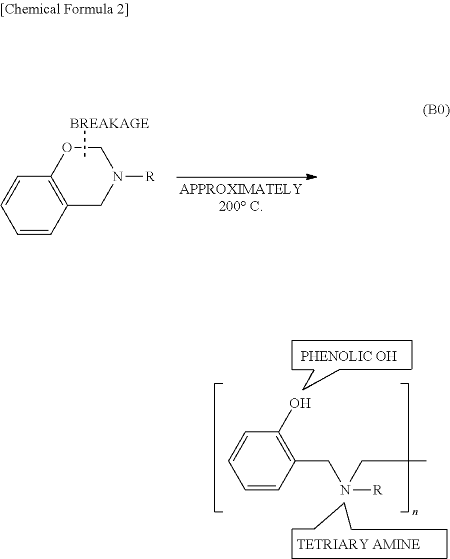

(where R is a substituent group, and n is an integer in the formula (B0))

The tertiary amine thus generated serves as a curing accelerator. Therefore, addition of another curing accelerator is unnecessary. The phenolic hydroxy group reacts with the main agent, so that the curing reaction proceeds, which enables the crosslink density of the cured product to be increased. Thus, when the curing agent contains the benzoxazine compound, the oxazine ring does not open before approximately 200° C., and therefore, increasing a start temperature of the curing reaction is possible. Conventionally, the thermosetting resin has a curing start temperature significantly lower than the melting point of the solder, and therefore, the curing reaction of the thermosetting resin starts at first. However, in the case of a thermosetting resin having a curing start temperature of approximately 200° C., the curing reaction of the thermosetting resin is less likely to proceed even around the melting point of the solder of 240° C. That is, at a time point at which the melting point of the solder is reached, the thermosetting resin is not completely cured. Moreover, when the curing agent contains the benzoxazine compound, simply mixing the main agent and the curing agent together at the ordinary temperature results in that the curing reaction is less likely to proceed. Therefore, it is possible to prolong a pot life. Note that dicyandiamide is known as a general curing agent, but with the dicyandiamide alone, the curing reaction does not proceed, and therefore, addition of a curing accelerator is necessary. However, when the curing accelerator is added to dicyandiamide, the curing reaction rapidly proceeds. Therefore, it is difficult to obtain an effect similar to that obtained in the case of the benzoxazine compound.

The benzoxazine compound is preferably one or more types of compounds selected from the group consisting of formulae (B1) to (B3) below.

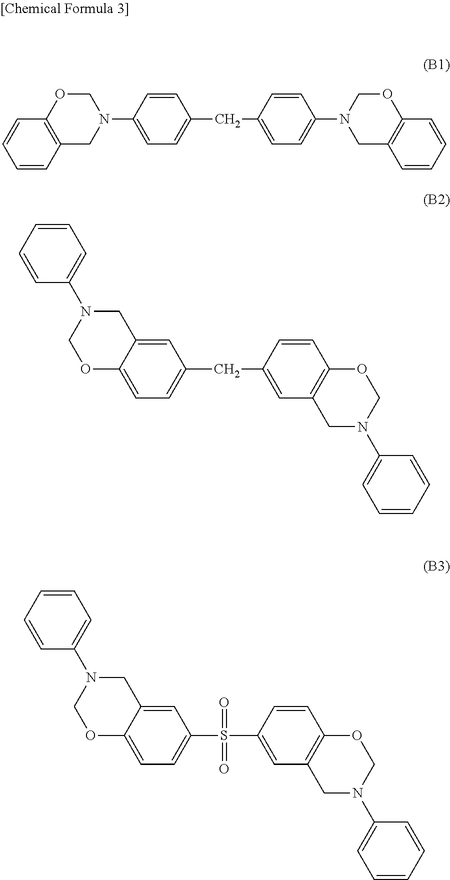 [SMILES: c1ccc2c(c1)CN(c1ccc(Cc3ccc(N4COc5ccccc5C4)cc3)cc1)CO2 ; c1ccc(N2COc3ccc(Cc4ccc5c(c4)CN(c4ccccc4)CO5)cc3C2)cc1 ; O=S(=O)(c1ccc2c(c1)CN(c1ccccc1)CO2)c1ccc2c(c1)CN(c1ccccc1)CO2]

The benzoxazine compound represented by the formula (B1) is a P-d-type benzoxazine compound. The benzoxazine compound represented by the formula (B1) generates no aniline even when the oxazine ring opens, which therefore enables a reduction in the moisture resistance of a cured product to be suppressed.

The benzoxazine compound represented by the formula (B2) is a bisphenol F-based benzoxazine compound.

The benzoxazine compound represented by the formula (B3) is a bisphenol S-based benzoxazine compound.

The benzoxazine compounds represented by formulae (B2) and (B3) are, in chemical structures, similar to the oxetane compound and the epoxy compound such as bisphenol F represented by the formula (O1). Therefore, the benzoxazine compounds in formula (B2) and formula (B3) have satisfactory compatibility with these compounds in formula (O1).

The benzoxazine compound is preferably greater than or equal to 10 parts by mass and less than or equal to 40 parts by mass with respect to 100 parts by mass of the main agent. When the benzoxazine compound is greater than or equal to 10 parts by mass, eventually reducing the formation of an uncured portion of the thermosetting resin to increase the strength of a cured product of the thermosetting resin are possible. When the benzoxazine compound is less than or equal to 40 parts by mass, it is possible to reduce rapid curing of thermosetting resin.

[Method for Producing Thermosetting Resin Composition]

The thermosetting resin composition according to the second embodiment may be produced as described below.

First, a thixotropy-imparting agent, a main agent (e.g., an oxetane compound), and other main agents (e.g., an epoxy compound) as necessary are blended together and are heated to melt the thixotropy-imparting agent, thereby obtaining a first mixture.

Then, with the first mixture, an activator and a benzoxazine compound as a curing agent are blended to obtain a mixture, which is kneaded with a kneader such as a planetary mixer, thereby obtaining a thermosetting resin composition. The activator and the curing agent used, if being solids, are preferably those sieved through, for example, a plain weave mesh screen having an opening of 125 μm and a wire diameter of 90 μm according to JIS Z 8801 for the purpose of uniform dispersion.

Similarly to the first embodiment, the thermosetting resin composition according to the second embodiment may be an uncured A-stage product (in liquid form) or a semi-cured B-stage product.

### Third Embodiment

[Thermosetting Sheet]

A thermosetting sheet 100 according to a third embodiment is formed from a semi-cured product of the thermosetting resin composition according to the first embodiment or the second embodiment. The thermosetting sheet 100 may be produced by applying, to a surface of a heat-resistant detachable support, a thermosetting resin composition as an uncured A-stage product, and by heating the thermosetting resin composition at 150° C. to 170° C. for 15 minutes to 30 minutes. The thermosetting sheet 100 thus obtained may be used instead of a liquid thermosetting resin referred to as an underfill.

### Fourth Embodiment

[Semiconductor Component]

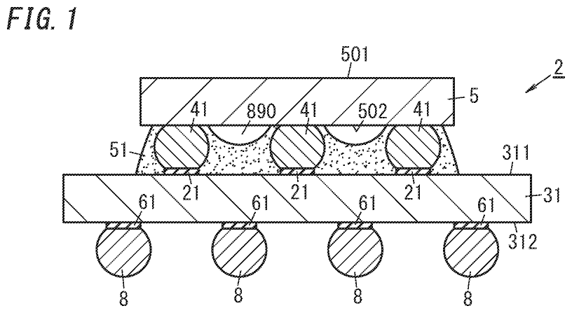

FIG. 1 is a schematic sectional view illustrating a semiconductor component 2 according to a fourth embodiment of the present invention. The semiconductor component 2 includes a semiconductor package 5, a first substrate 31, first solder bonding parts 41, and a first resin part 51. As illustrated in FIG. 1, the semiconductor component 2 may further include second solder bumps 8. These elements included in the semiconductor component 2 will be described below. Note that in the semiconductor component 2, the vertical direction is defined with the semiconductor package 5 being set as an upper element and the first substrate 31 being set as a lower element. The definition, however, is made merely for the sake of convenient description. A view in the vertical direction is a plan view. Moreover, ordinal numbers such as “first” are applied to avoid confusion of components and do not mean numerical limitations of the components.

(Semiconductor Package)

The semiconductor package 5 is not particularly limited. Specific examples of the semiconductor package 5 include a ball grid array (BGA) and a chip size package (CSP). The semiconductor package 5 has a first surface 501. The semiconductor package 5 has a second surface 502 on an opposite side from the first surface 501. That is, the first surface 501 and the second surface 502 are respectively an upper surface and a lower surface of the semiconductor package 5 and form front and back surfaces of the semiconductor package 5.

(First Substrate)

The first substrate 31 is, but not particularly limited to, a printed wiring board. The first substrate 31 has a first surface 311. The first substrate 31 has a second surface 312 on an opposite side from the first surface 311. That is, the first surface 311 and the second surface 312 are respectively an upper surface and a lower surface of the first substrate 31 and form front and back surfaces of the first substrate 31. The first surface 311 of the first substrate 31 is provided with a first pad 21. At least one or more first pads 21 are provided.

(First Solder Bonding Part)

Each first solder bonding part 41 electrically connects the semiconductor package 5 to a corresponding one of the first pads 21 on the first substrate 31. Moreover, the first solder bonding part 41 physically couple the semiconductor package 5 to the first substrate 31.

The melting point of the first solder bonding part 41 is preferably higher than or equal to 100° C. and lower than or equal to 240° C., more preferably higher than or equal to 130° C. and lower than or equal to 240° C. When the melting point of the first solder bonding part 41 is higher than or equal to 100° C., it is possible to obtain satisfactory strength of the first solder bonding part 41. When the melting point of the first solder bonding part 41 is lower than or equal to 240° C., a first thermosetting resin composition 11 for forming the first resin part 51 which will be described later is suppressed from being cured before solder is melted during soldering.

The first solder bonding parts 41 are preferably made of Sn—Ag—Cu-based solder or Sn—Bi-based solder. The melting point of Sn—Ag—Cu-based solder is 218° C. to 219° C. The melting point of Sn—Bi-based solder is 138° C. to 139° C. Such solder enables the coupling strength of the first solder bonding parts 41 to be increased and enables the occurrence of failure such as a crack and the like to be reduced. Moreover, such solder is lead-free solder and thus provides the advantage of being harmless to the human body and the environment.

(First Resin Part)

The first resin part 51 is in contact with the first solder bonding parts 41. More specifically, the first resin part 51 is in contact with peripheral surfaces of the first solder bonding parts 41. Preferably, the first resin part 51 is bonded to at least one of the semiconductor package 5 or the first substrate 31. This enables the first resin part 51 to reinforce the first solder bonding parts 41. Note that the semiconductor component 2 shown in FIG. 1 has a hollow 890 between the second surface 502 and the first resin part 51 of the semiconductor package 5, but the hollow 890 does not necessarily have to be provided. That is, a space between the semiconductor package 5 and the first substrate 31, except for the first solder bonding parts 41, may be filled with the first resin part 51.

The first resin part 51 has an electrical insulation property. Thus, as illustrated in FIG. 1, even when the first resin part 51 is in contact with two or more first solder bonding parts 41, it is possible to reduce short-circuiting.

The first resin part 51 is formed from a cured product of the first thermosetting resin composition 11. The first thermosetting resin composition 11 is similar to the thermosetting resin composition according to the first or second embodiment. Thus, the first thermosetting resin composition 11 contains at least one of a di- or higher functional oxetane compound or a benzoxazine compound having two or more oxazine rings. Thus, between each of the first solder bonding parts 41 and a corresponding one of the first pads 21, it is possible to suppress the first thermosetting resin composition 11 from curing, and it is possible to satisfactorily connect the first solder bonding parts 41 to the respective first pads 21. In other words, it is possible to prevent the first thermosetting resin composition 11 from inhibiting the electrical connection between the first solder bonding parts 41 and the respective first pads 21.

When the first thermosetting resin composition 11 contains a di- or higher epoxy compound, reducing the formation of an uncured portion of the first thermosetting resin composition 11 to increase the strength of the first resin part 51 as the cured product of the first thermosetting resin composition 11 are possible.

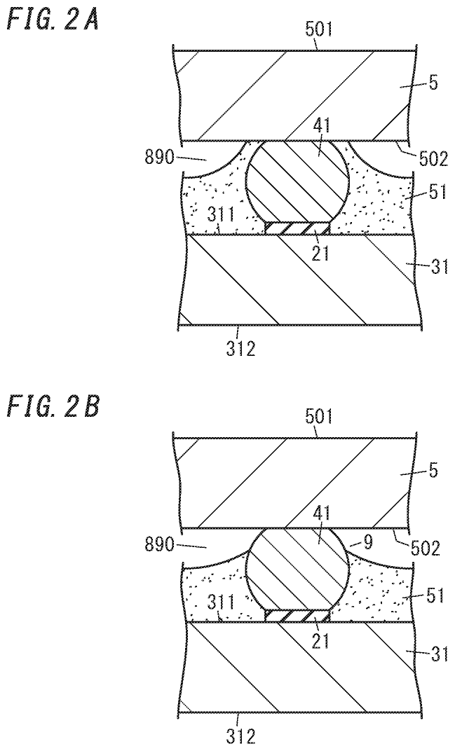

Here, FIG. 2A is a schematic sectional view illustrating part of the semiconductor component 2 shown in FIG. 1. As illustrated in FIG. 2A, the entirety of a side surface of the first solder bonding part 41 may be covered with the first resin part 51 so that the first solder bonding part 41 is not exposed to the outside. In this case, the first resin part 51 is also in contact with the second surface 502 of the semiconductor package 5 and the first surface 311 of the first substrate 31. This improves the effect of reinforcing the first solder bonding part 41 by the first resin part 51.

Moreover, FIG. 2B is a schematic sectional view illustrating another part of the semiconductor component 2 shown in FIG. 1. As illustrated in FIG. 2B, the first resin part 51 may have a gap 9 formed such that part of the first solder bonding part 41 is exposed to the outside. The gap 9 is in communication with the hollow 890. When heated to the melting point or higher, the first solder bonding part 41 is remelted to expand. Thus, if the first resin part 51 covers the entirety of the side surface of the first solder bonding part 41 to seal the first solder bonding part 41, there is no place into which melted solder flows. Therefore, the first resin part 51 may explode, which may lead to a risk of causing solder flash or a solder bridge. In contrast, the first resin part 51 has the gap 9 formed as illustrated in FIG. 2B, and therefore, even when the first solder bonding part 41 is remelted, a solder portion by which the volume of the solder increases goes out to the hollow 890 and the like through the gap 9. When the first solder bonding parts 41 are then cooled to a temperature lower than the melting point, the solder portion located outside returns to its original location through the gap 9 and forms the first solder bonding part 41 again. Thus, the occurrence of the solder flash and the solder bridge is reduced.

In FIG. 2B, the gap 9 is formed such that the first resin part 51 does not come into contact with the second surface 502 of the semiconductor package 5, but the location where the gap 9 is formed is not particularly limited.

When secondary packaging is performed after primary packaging, a location where the primary packaging is performed can be reheated. Therefore, the primary packaging preferably adopts the configuration shown in FIG. 2B. Here, the primary packaging means mounting the semiconductor package 5 on the first substrate 31. The secondary packaging means mounting the semiconductor component 2 on a second substrate 32 which will be described later.

Note that if the first solder bonding part 41 which has once been formed is not reheated to the melting point or higher, the first resin part 51 does not have to have the gap 9. This case includes, for example, a case where the secondary packaging is not performed, and a case where a reflow heating temperature of the secondary packaging is lower than the heating temperature of reflow soldering of the primary packaging.

(Second Solder Bump)

As described above, the semiconductor component 2 may further include the second solder bumps 8. In this case, the second surface 312 of the first substrate 31 has at least one or more lands 61. Each land 61 is provided with the second solder bump 8. The second solder bumps 8 enable the semiconductor component 2 to be mounted on the second substrate 32 which will be described later. In this case, the first substrate 31 may be an interposer. The first substrate 31 serving as such an interposer enables a wiring pitch of the semiconductor package 5 of the semiconductor component 2 to be converted into a wiring pitch of the second substrate 32.

[Method for Producing Semiconductor Component]

A method for producing the semiconductor component 2 according to the fourth embodiment includes step A1 to step D1. Each of the steps will be described below.

(Step A1)

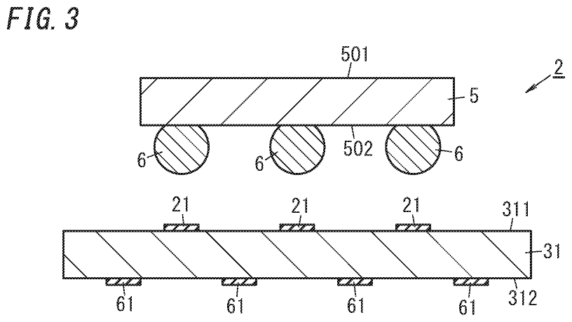

FIG. 3 is a schematic sectional view illustrating step A1. Step A1 is a step of preparing the semiconductor package 5 and the first substrate 31.

The semiconductor package 5 is specifically a chip size package (CSP) or the like. The semiconductor package 5 is provided with a first solder bump 6. More specifically, the first solder bump 6 is formed on the second surface 502 of the semiconductor package 5. At least one or more first solder bumps 6 are provided. The first solder bumps 6 are preferably made of Sn—Ag—Cu-based solder or Sn—Bi-based solder. Such solder enables the coupling strength of the first solder bonding parts 41 to be increased and enables the occurrence of failure such as a crack and the like to be reduced.

The first substrate 31 is specifically a printed wiring board. The first surface 311 of the first substrate 31 is provided with first pads 21. The first pads 21 provided are the same in number as the first solder bumps 6. The first solder bumps 6 and the first pads 21 are arranged to face each other on a one-to-one basis when the second surface 502 of the semiconductor package 5 faces the first surface 311 of the first substrate 31. That is, the first solder bumps 6 and the first pads 21 are in the same positional relationship. The second surface 312 of the first substrate 31 may have the lands 61. The lands 61 may be utilized for the secondary packaging.

(Step B1)

Step B1 is a step of applying or disposing the first thermosetting resin composition 11 to or on the first surface 311 of the first substrate 31.

Here, step B1 may be divided into step B1-1 and step B1-2. In step B1-1, the first thermosetting resin composition 11 is applied to the first surface 311 of the first substrate 31. In step B1-2, the first thermosetting resin composition 11 is disposed on the first surface 311 of the first substrate 31. That is, depending on the form (liquid form or not) of the first thermosetting resin composition 11, either step B1-1 or step B1-2 is adopted. Specifically, when the first thermosetting resin composition 11 is an uncured A-stage product (liquid form), step B1-1 is adopted, whereas when the first thermosetting resin composition 11 is a semi-cured B-stage product, step B1-2 is adopted. Step B1-1 and step B1-2 will be described below.

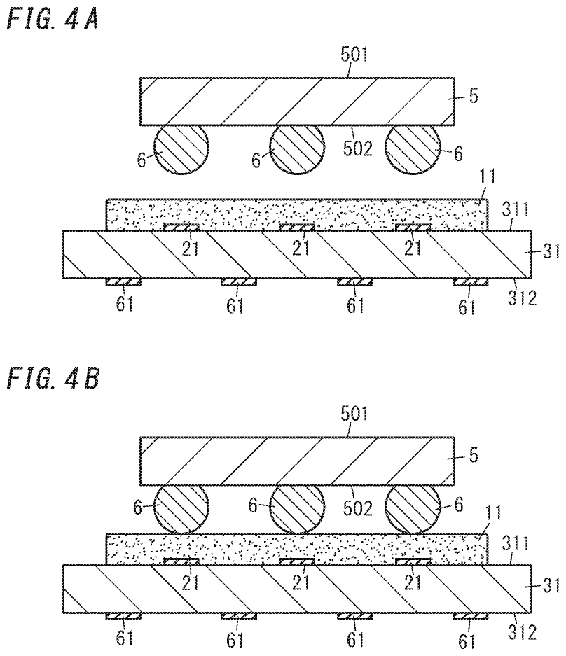

First of all, step B1-1 will be described. Step B1-1 is shown in FIG. 4A. In this case, the first thermosetting resin composition 11 is an uncured A-stage product and is similar to the thermosetting resin composition according to the first or second embodiment. Thus, the first thermosetting resin composition 11 contains: at least one of the di- or higher functional oxetane compound or the benzoxazine compound having two or more oxazine rings; an activator; and a thixotropy-imparting agent. The first thermosetting resin composition 11 preferably further contains a di- or higher functional epoxy compound.

As described above, the first thermosetting resin composition 11 is in liquid form. As illustrated in FIG. 4A, the first thermosetting resin composition 11 is applied to the first surface 311 of the first substrate 31. In this case, the first thermosetting resin composition 11 may be applied to the first surface 311 of the first substrate 31 except for the first pads 21, or the first thermosetting resin composition 11 may be applied to surfaces of the first pads 21. The first thermosetting resin composition 11 may be applied to be in contact with two or more first pads 21. This is because the first thermosetting resin composition 11 has an electrical insulation property. It is possible to reduce short-circuiting even when the first thermosetting resin composition 11 is cured to form the first resin part 51 while being in contact with the two or more first pads 21. A method for applying the first thermosetting resin composition 11 to the first surface 311 of the first substrate 31 is not particularly limited. Specific examples of the application method include screen printing and dispensing.

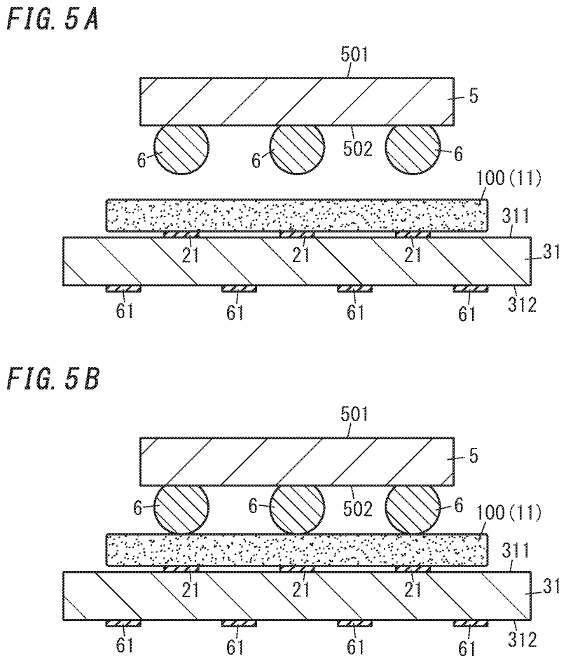

Next, step B1-2 will be described. Step B1-2 is shown in FIG. 5A. In this case, the first thermosetting resin composition 11 is a semi-cured B-stage product and is similar to the thermosetting sheet 100 of the third embodiment. Thus, the thermosetting sheet 100 contains: at least one of a di- or higher functional oxetane compound or a benzoxazine compound having two or more oxazine rings; an activator; and a thixotropy-imparting agent. The thermosetting sheet 100 preferably further contains a di- or higher functional epoxy compound.

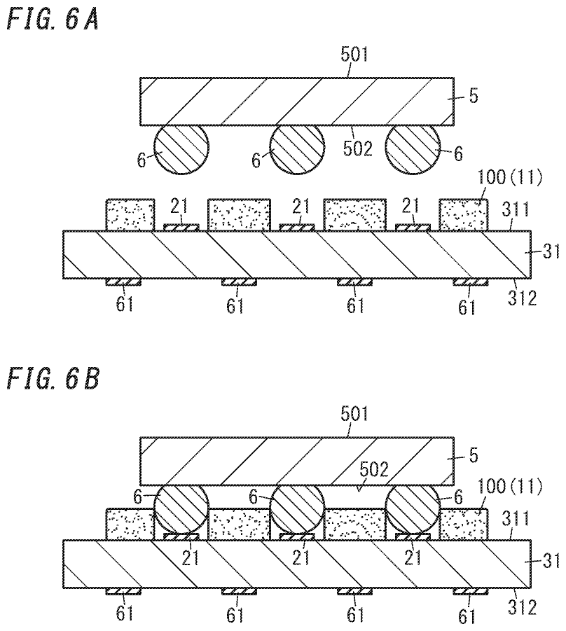

As illustrated in FIG. 5A, the thermosetting sheet 100 is disposed on the first surface 311 of the first substrate 31. In this case, the thermosetting sheet 100 may be disposed on a surface of the first pad 21. The thermosetting sheet 100 may be disposed to be in contact with two or more first pads 21. This is because the thermosetting sheet 100 has an electrical insulation property. It is possible to reduce short-circuiting even when the thermosetting sheet 100 is cured to form the first resin part 51 while being in contact with the two or more first pads 21. Note that as illustrated in FIG. 6A, the thermosetting sheet 100 may be disposed on the first surface 311 of the first substrate 31 except for the first pads 21. More specifically, through holes may be formed in one thermosetting sheet 100, and the one thermosetting sheet 100 may be disposed on the first surface 311 of the first substrate 31 such that the first pads 21 are exposed through the through holes, or a plurality of thermosetting sheets 100 may be disposed around the first pads 21.

(Step C1)

Step C1 is a step of disposing the first solder bumps 6 on the first pads 21. At this time, the first solder bumps 6 may be disposed on the first pads 21 via the first thermosetting resin composition 11 as illustrated in FIGS. 4B and 5B, or the first solder bumps 6 may be directly disposed on the first pads 21 as illustrated in FIG. 6B.

Here, FIG. 4B shows a state after FIG. 4A. That is, in FIG. 4B, the first thermosetting resin composition 11 as an uncured A-stage product (in liquid form) has an interposed portion between each first solder bump 6 and its corresponding first pad 21. The interposed portion of the first thermosetting resin composition 11 is pushed by the first solder bump 6 to the periphery of the first pad 21 in step D1 which will be described later.

Moreover, FIG. 5B shows a state after FIG. 5A. That is, in FIG. 5B, the first thermosetting resin composition 11 as a semi-cured B-stage product, specifically, the thermosetting sheet 100 has an interposed portion between each first solder bump 6 and its corresponding first pad 21. The interposed portion of the thermosetting sheet 100 is pushed by the first solder bump 6 to the periphery of the first pad 21 while being melted in step D1 which will be described later.

FIG. 6B shows a state after FIG. 6A. That is, in FIG. 6B, the first solder bumps 6 are directly in contact with the first pads 21.

(Step D1)

Step D1 is a step of heating, in a state shown in one of FIGS. 4B, 5B, and 6B, the semiconductor package 5 and the first substrate 31 for four minutes or longer to perform reflow soldering such that the peak temperature is higher than or equal to 220° C. and lower than or equal to 260° C. The upper limit of a heating time is not particularly limited but is, for example, 10 minutes, and in particular, the upper limit of the heating time at a peak temperature is, for example, 1 minute. The peak temperature is preferably set to a temperature higher than the melting point of the solder for forming the first solder bumps 6 by 20° C. to 30° C.

The rate of temperature rise to the peak temperature is preferably higher than or equal to 1° C./sec. and lower than or equal to 4° C./sec. When the rate of temperature rise is higher than or equal to 1° C./sec., it is possible to reduce an increase in viscosity due to the curing reaction of the first thermosetting resin composition 11 proceeding before the melting point of the solder is reached. When the rate of temperature rise is lower than or equal to 4° C./sec., it is possible to satisfactorily secure a time for removing an oxide film of the solder by the reduction action of the activator. This can further enhance the wettability of the solder. A heating start temperature is generally, but not particularly limited to, an ordinary temperature.

Here, the first thermosetting resin composition 11 contains at least one of the di- or higher functional oxetane compound or the benzoxazine compound having two or more oxazine rings. This is divided into three cases. That is, a first case is a case where the first thermosetting resin composition 11 contains the oxetane compound but does not contain the benzoxazine compound. A second case is a case where the first thermosetting resin composition 11 does not contain the oxetane compound but contains the benzoxazine compound. A third case is a case where the first thermosetting resin composition 11 contains both the oxetane compound and the benzoxazine compound.

In the first case, when heating is performed for the soldering, the oxetane compound reduces the curing speed of the first thermosetting resin composition 11 to be lower than the speed at which the solder melts.

In the second case, when heating is performed for the soldering, the benzoxazine compound increases the curing start temperature of the first thermosetting resin composition 11. This does not necessarily mean that the curing start temperature of the first thermosetting resin composition 11 is higher than the melting point of the solder, but this means that the curing start temperature of the first thermosetting resin composition 11 is not too low as compared to the melting point of the solder. The difference between the melting point of the solder and the curing start temperature of the first thermosetting resin composition 11 varies in accordance with an extent to which the curing reaction of the first thermosetting resin composition 11 proceeds, but the difference is, as a rough reference, preferably smaller than or equal to 40° C. when the melting point of the solder is high and the curing start temperature of the first thermosetting resin composition 11 is low.

In the third case, as a synergetic effect of the first and the second cases, the curing speed of the first thermosetting resin composition 11 decreases, and the curing start temperature increases.

In each of the first to third cases, it is possible to reduce curing of the first thermosetting resin composition 11 before the solder of the first solder bumps 6 is melted during the soldering.

More specifically, in FIG. 4B, each first solder bump 6 is melted while the first solder bump 6 pushes the first thermosetting resin composition 11 in liquid form to the periphery of the first pad 21, and each first solder bump 6 comes into contact with the first pad 21. Then, the first thermosetting resin composition 11 starts curing, thereby forming the first resin part 51. The solder melded and in contact with the first pad 21 is cured through subsequent cooling, thereby forming the first solder bonding part 41.

Moreover, in FIG. 5B, each first solder bump 6 is melted while pushing, to the periphery of the first pad 21, the thermosetting sheet 100 which is started to melt, and each first solder bump 6 comes into contact with the first pad 21. Then, the thermosetting sheet 100 melted starts curing, thereby forming the first resin part 51. The solder melded and in contact with the first pad 21 is cured through subsequent cooling, thereby forming the first solder bonding part 41.

Moreover, in FIG. 6B, each first solder bump 6 which is in contact with the first pad 21 is melted by being heated and curs through subsequent cooling, thereby forming the first solder bonding part 41. The first thermosetting resin composition 11 disposed in the periphery of each first pad 21 starts curing while being in contact with the periphery of the first solder bonding part 41 which is melted by being heated and is in the course of formation, and thereby, the first resin part 51 is formed.

In each of the first to third cases, the first thermosetting resin composition 11 preferably further contains the di- or higher functional epoxy compound. This enables the formation of an uncured portion of the first thermosetting resin composition 11 to eventually be reduced and the strength of the first resin part 51 as the cured product of the first thermosetting resin composition 11 to be increased.

After completion of the reflow soldering, the semiconductor component 2 can be obtained. In the semiconductor component 2 shown in FIG. 1, the second surface 312 of the first substrate 31 is provided with the lands 61, and each formed on the land 61 is provided with the second solder bumps 8. However, when secondary packaging is not performed, the lands 61 and the second solder bumps 8 are not required.

Preferably, neither the activator nor the thixotropy-imparting agent is substantially left in the first resin part 51. However, small amounts of the activator and the thixotropy-imparting agent may be left as long as the amounts do not impair reliability. Accordingly, it is unnecessary to remove the activator and the thixotropy-imparting agent through washing.

### Fifth Embodiment

[Semiconductor Mounted Article]

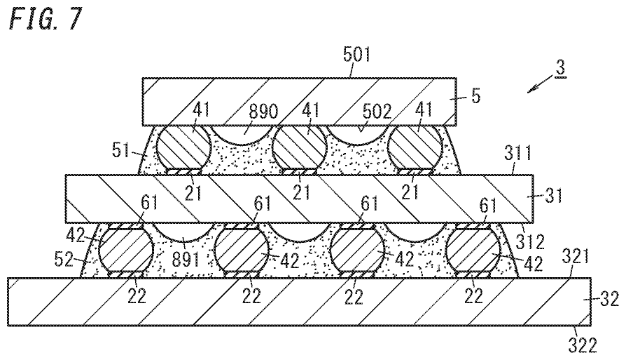

FIG. 7 is a schematic sectional view illustrating a semiconductor mounted article 3 according to a fifth embodiment of the present invention. The semiconductor mounted article 3 includes a semiconductor package 5, a first substrate 31, first solder bonding parts 41, a first resin part 51, a second substrate 32, second solder bonding parts 42, and a second resin part 52. These elements included in the semiconductor mounted article 3 will be described below. Note that in the semiconductor mounted article 3, a configuration including the semiconductor package 5, the first substrate 31, the first solder bonding parts 41, and the first resin part 51 is similar to the configuration of the semiconductor component 2 according to the fourth embodiment. In the semiconductor mounted article 3, the vertical direction is defined with the semiconductor package 5 being set as an upper element and the second substrate 32 being set as a lower element. The definition, however, is made merely for the sake of convenient description. A view in the vertical direction is a plan view. Moreover, ordinal numbers such as “first” are applied to avoid confusion of components and do not mean numerical limitations of the components.

(Semiconductor Package)

The semiconductor package 5 is similar to the semiconductor package 5 of the fourth embodiment.

(First Substrate and Second Substrate)

The first substrate 31 is similar to the first substrate 31 of the fourth embodiment.

The second substrate 32 may be, but is not particularly limited to, a printed wiring board. The second substrate 32 has a first surface 321. The second substrate 32 has a second surface 322 on an opposite side from the first surface 321. That is, the first surface 321 and the second surface 322 are respectively an upper surface and a lower surface of the second substrate 32 and form front and back surfaces of the second substrate 32. The first surface 321 of the second substrate 32 is provided with a second pad 22. At least one or more second pads 22 are provided. The second pads 22 which are the same in number as the lands 61 are formed on the first substrate 31.

The first substrate 31 functions as an interposer and thus enables a wiring pitch of the semiconductor package 5 to be converted into a wiring pitch of the second substrate 32. The second substrate 32 may be a motherboard or mainboard.

(First Solder Bonding Part and Second Solder Bonding Part)

The first solder bonding parts 41 are similar to the first solder bonding parts 41 of the fourth embodiment.

The second solder bonding parts 42 electrically connect the lands 61 on the first substrate 31 to the respective second pads 22 on the second substrate 32. Moreover, the second solder bonding parts 42 physically couple the first substrate 31 to the second substrate 32.

The melting point of the second solder bonding parts 42 is preferably higher than or equal to 100° C. and lower than or equal to 240° C., more preferably higher than or equal to 130° C. and lower than or equal to 240° C. When the melting point of the second solder bonding parts 42 is higher than or equal to 100° C., it is possible to achieve sufficient strength of the second solder bonding part 42. When the melting point of the second solder bonding part 42 is lower than or equal to 240° C., a second thermosetting resin composition 12 forming the second resin part 52 which will be described later is suppressed from being cured before the solder is melted during soldering in the secondary packaging.

The second solder bonding parts 42 are preferably made of Sn—Ag—Cu-based solder or Sn—Bi-based solder. The melting point of Sn—Ag—Cu-based solder is 218° C. to 219° C. The melting point of Sn—Bi-based solder is 138° C. to 139° C. Such solder enables the coupling strength of the second solder bonding parts 42 to be increased and enables the occurrence of failure such as a crack and the like to be reduced. Moreover, such solder is lead-free solder and thus provides the advantage of being harmless to the human body and the environment.

The melting point of the first solder bonding part 41 may be the same as or different from the melting point of the second solder bonding part 42.

If the melting point of the second solder bonding part 42 is lower than the melting point of the first solder bonding part 41, heating to such an extent as the melting point of the first solder bonding part 41 is not required during the soldering in the secondary packaging. Therefore, it is possible to avoid remelting of the first solder bonding parts 41.

If the melting point of the second solder bonding part 42 is higher than or equal to the melting point of the first solder bonding part 41, the first solder bonding parts 41 can be remelted during the soldering in the secondary packaging. In this case, if the first resin part 51 is bonded to the semiconductor package 5 and the first substrate 31, the first resin part 51 can reduce separation of the semiconductor package 5 from the first substrate 31 even when the first solder bonding parts 41 are remelted.

(First Resin Part and Second Resin Part)

The first resin part 51 is similar to the first resin part 51 of the fourth embodiment.

The second resin part 52 is in contact with the second solder bonding parts 42. More specifically, the second resin part 52 is in contact with peripheral surfaces of the second solder bonding parts 42. Preferably, the second resin part 52 is bonded to at least one of the first substrate 31 or the second substrate 32. This enables the second resin part 52 to reinforce the second solder bonding parts 42. Note that the semiconductor mounted article 3 shown in FIG. 7 has a hollow 891 between the second surface 312 of the first substrate 31 and the second resin part 52, but the hollow 891 does not necessarily have to be provided. That is, a space between the first substrate 31 and the second substrate 32, except for the second solder bonding parts 42, may be filled with the second resin part 52.

The second resin part 52 has an electrical insulation property. Thus, as illustrated in FIG. 7, even when the second resin part 52 is in contact with two or more second solder bonding parts 42, it is possible to reduce short-circuiting.

The second resin part 52 is formed from a cured product of the second thermosetting resin composition 12. The second thermosetting resin composition 12 is similar to the thermosetting resin composition according to the first or second embodiment. Thus, the second thermosetting resin composition 12 contains at least one of a di- or higher functional oxetane compound or a benzoxazine compound having two or more oxazine rings. This suppresses, between each of the second solder bonding parts 42 and a corresponding one of the second pads 22, the second thermosetting resin composition 12 from being cured, and it is thus possible to satisfactorily connect the second solder bonding parts 42 to the respective second pads 22. In other words, it is possible to prevent the second thermosetting resin composition 12 from inhibiting the electrical connection between the second solder bonding parts 42 and the respective second pads 22.

When the second thermosetting resin composition 12 contains a di- or higher epoxy compound, reducing the formation of an uncured portion of the second thermosetting resin composition 12 to increase the strength of the second resin part 52 as a cured product of the second thermosetting resin composition 12 are possible.

Here, in the same manner as the case of the first resin part 51 illustrated in FIG. 2A, the entirety of a side surface of the second solder bonding part 42 may be covered with the second resin part 52 so that the second solder bonding part 42 is not exposed to the outside. In this case, the second resin part 52 is also in contact with the second surface 312 of the first substrate 31 and the first surface 321 of the second substrate 32. This improves the effect of reinforcing the second solder bonding part 42 by the second resin part 52.

Moreover, in the same manner as the case of the first resin part 51 illustrated in FIG. 2B, the second resin part 52 may have a gap formed such that part of the second solder bonding part 42 is exposed to the outside. Also in this case, the occurrence of the solder flash and the solder bridge is reduced.

Note that if the second solder bonding part 42 which has once been formed is not reheated to the melting point or higher, the second resin part 52 does not have to have the gap.

[Method for Producing Semiconductor Mounted Article]

A method for producing the semiconductor mounted article 3 according to the fifth embodiment includes step A2 to step I2. Here, step A2 to step D2 are similar to step A1 to step D1 of the fourth embodiment. However, at least one or more lands 61 are formed on the second surface 312 of the first substrate 31. Thus, in the fifth embodiment, steps until the semiconductor component 2 is produced are similar to those in the fourth embodiment. Thus, the description of steps A2 to D2 is omitted, and subsequent steps E2 to 12 will be sequentially described.

(Step E2)

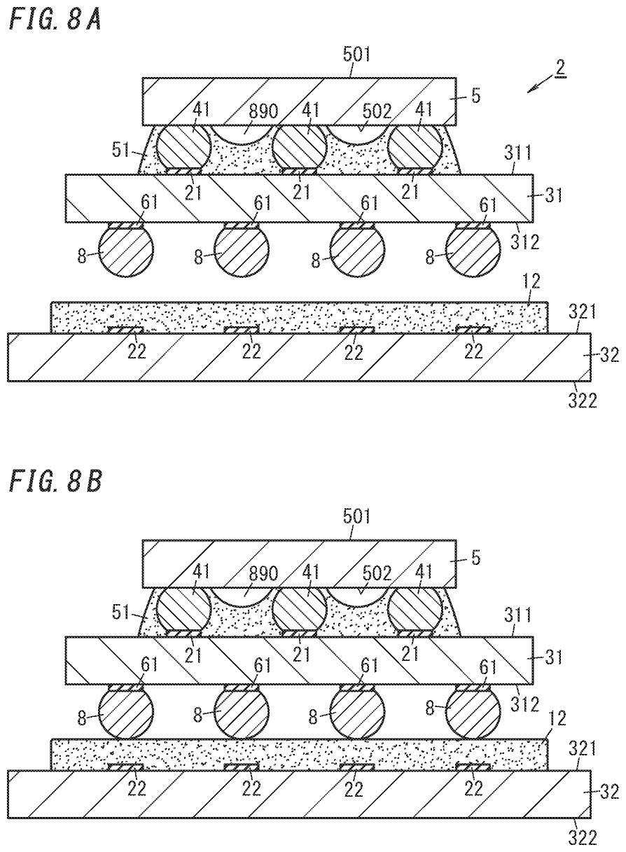

As illustrated in FIG. 8A, step E2 is a step of forming a second solder bump 8 on a land 61. If a plurality of lands 61 are provided on the second surface 312 of the first substrate 31, second solder bumps 8 are formed on the respective lands 61. The second solder bumps 8 are preferably made of Sn—Ag—Cu-based solder or Sn—Bi-based solder. Such solder enables the coupling strength of the second solder bonding parts 42 to be increased and enables the occurrence of failure such as a crack and the like to be reduced.

(Step F2)

As illustrated in FIG. 8A, step F2 is a step of preparing the second substrate 32.

The second substrate 32 is specifically a printed wiring board. The first surface 321 of the second substrate 32 is provided with second pads 22. The second pads 22 provided are the same in number as the second solder bumps 8. The second solder bumps 8 and the second pads 22 are arranged to face each other on a one-to-one basis when the second surface 312 of the first substrate 31 and the first surface 321 of the second substrate 32 face each other. That is, the second solder bumps 8 and the second pads 22 are in the same positional relationship. Although not shown in the figure, the second surface 322 of the second substrate 32 may have lands. The lands may be utilized for tertiary packaging. Here, the tertiary packaging means mounting the semiconductor mounted article 3 on another substrate.

(Step G2)

Step G2 is a step of applying or disposing the second thermosetting resin composition 12 to or on the first surface 321 of the second substrate 32.

Here, step G2 may be divided into step G2-1 and step G2-2. In step G2-1, the second thermosetting resin composition 12 is applied to the first surface 321 of the second substrate 32. In step G2-2, the second thermosetting resin composition 12 is disposed on the first surface 321 of the second substrate 32. That is, depending on the form (liquid form or not) of the second thermosetting resin composition 12, either step G2-1 or step G2-2 is adopted. Specifically, when the second thermosetting resin composition 12 is an uncured A-stage product (liquid form), step G2-1 is adopted, whereas when the second thermosetting resin composition 12 is a semi-cured B-stage product, step G2-2 is adopted. Step G2-1 and step G2-2 will be described below.

First of all, step G2-1 will be described. Step G2-1 is shown in FIG. 8A. In this case, the second thermosetting resin composition 12 is an uncured A-stage product and is similar to the thermosetting resin composition according to the first or second embodiment. Thus, the second thermosetting resin composition 12 contains: at least one of the di- or higher functional oxetane compound or the benzoxazine compound having two or more oxazine rings; an activator; and a thixotropy-imparting agent. The second thermosetting resin composition 12 preferably further contains a di- or higher functional epoxy compound. Note that the composition of the second thermosetting resin composition 12 may be the same as or different from the composition of the first thermosetting resin composition 11.

As described above, the second thermosetting resin composition 12 is in liquid form. As illustrated in FIG. 8A, the second thermosetting resin composition 12 is applied to the first surface 321 of the second substrate 32. In this case, the second thermosetting resin composition 12 may be applied to the first surface 321 of the second substrate 32 except for the second pads 22, but the second thermosetting resin composition 12 may be applied to surfaces of the second pads 22. The second thermosetting resin composition 12 may be applied to be in contact with two or more second pads 22. This is because the second thermosetting resin composition 12 has an electrical insulation property. It is possible to reduce short-circuiting even when the second thermosetting resin composition 12 is cured to form the second resin part 52 while being in contact with the two or more second pads 22. A method for applying the second thermosetting resin composition 12 to the first surface 321 of the second substrate 32 is not particularly limited. Specific examples of the application method include screen printing and dispensing.

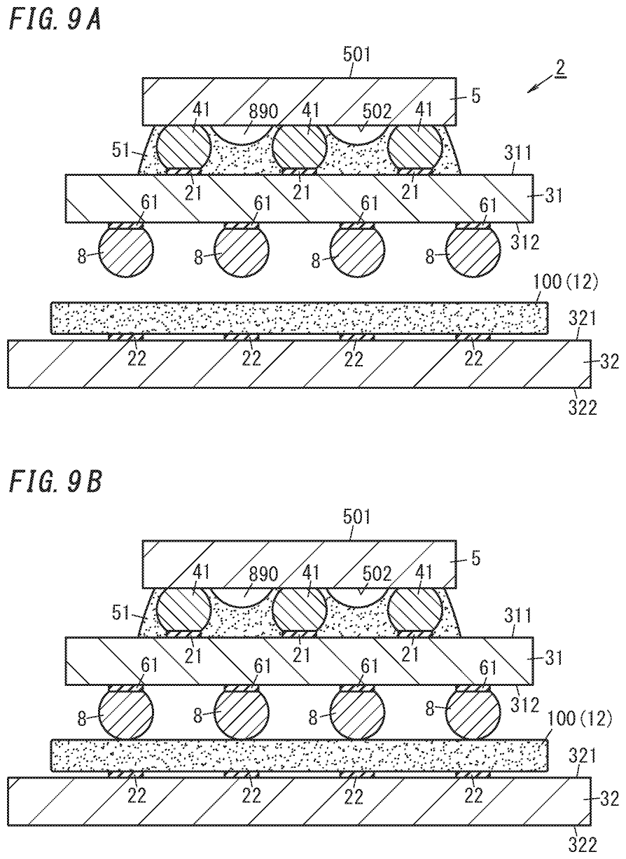

Next, step G2-2 will be described. Step G2-2 is shown in FIG. 9A. In this case, the second thermosetting resin composition 12 is a semi-cured B-stage product and is similar to the thermosetting sheet 100 of the third embodiment. Thus, the thermosetting sheet 100 contains: at least one of a di- or higher functional oxetane compound or a benzoxazine compound having two or more oxazine rings; an activator; and a thixotropy-imparting agent. The thermosetting sheet 100 preferably further contains a di- or higher functional epoxy compound.

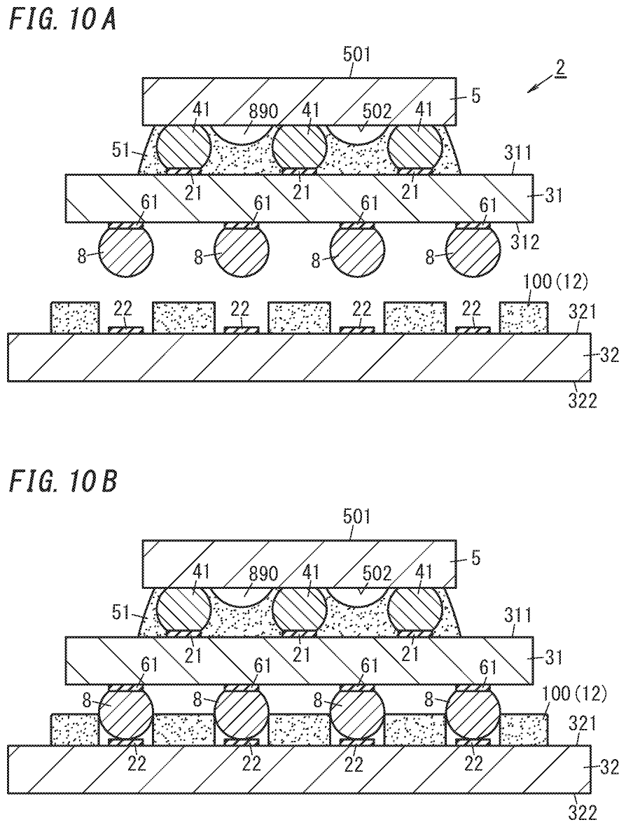

As illustrated in FIG. 9A, the thermosetting sheet 100 is disposed on the first surface 321 of the second substrate 32. In this case, the thermosetting sheet 100 may be disposed on a surface of the second pad 22. The thermosetting sheet 100 may be disposed to be in contact with two or more second pads 22. This is because the thermosetting sheet 100 has an electrical insulation property. It is possible to reduce short-circuiting even when the thermosetting sheet 100 is cured to form the second resin part 52 while being in contact with two or more second pads 22. Note that as illustrated in FIG. 10A, the thermosetting sheet 100 may be disposed on the first surface 321 of the second substrate 32 except for the second pads 22. More specifically, through holes may be formed in one thermosetting sheet 100, and the one thermosetting sheet 100 may be disposed on the first surface 321 of the second substrate 32 such that the second pads 22 are exposed through the through holes, or a plurality of thermosetting sheets 100 may be disposed around the second pads 22.

(Step H2)

Step H2 is a step of disposing the second solder bumps 8 on the second pads 22. At this time, as illustrated in FIGS. 8B and 9B, the second solder bumps 8 may be disposed on the second pads 22 via the second thermosetting resin composition 12, or as illustrated in FIG. 10B, the second solder bumps 8 may be directly disposed on the second pads 22.

Here, FIG. 8B shows a state after FIG. 8A. That is, in FIG. 8B, the second thermosetting resin composition 12 as an uncured A-stage product (in liquid form) has an interposed portion between each second solder bump 8 and its corresponding second pad 22. The interposed portion of the second thermosetting resin composition 12 is pushed by the second solder bump 8 to the periphery of the second pad 22 in step I2 which will be described later.

FIG. 9B shows a state after FIG. 9A. That is, in FIG. 9B, the second thermosetting resin composition 12 as a semi-cured B-stage product, specifically, the thermosetting sheet 100 has an interposed portion between each second solder bump 8 and its corresponding second pad 22. The interposed portion of the thermosetting sheet 100 is pushed by the second solder bump 8 to the periphery of the second pad 22 while being melted in step I2 which will be described later.

FIG. 10B shows a state after FIG. 10A. That is, in FIG. 10B, the second solder bumps 8 are directly in contact with the second pads 22.

(Step I2)

In step I2, in a state shown in one of FIGS. 8B, 9B, and 10B, the semiconductor package 5, the first substrate 31, and the second substrate 32 are heated for four minutes or longer to perform reflow soldering such that the peak temperature is higher than or equal to 220° C. and lower than or equal to 260° C. The upper limit of a heating time is not particularly limited but is, for example, 10 minutes, and in particular, the upper limit of the heating time at a peak temperature is, for example, 1 minute. The peak temperature is preferably set to a temperature higher than the melting point of the solder for forming the second solder bumps 8 by 20° C. to 30° C.

The rate of temperature rise to the peak temperature is preferably higher than or equal to 1° C./sec. and lower than or equal to 4° C./sec. When the rate of temperature rise is higher than or equal to 1° C./sec., it is possible to reduce an increase in viscosity due to the curing reaction of the second thermosetting resin composition 12 proceeding before the melting point of the solder is reached. When the rate of temperature rise is lower than or equal to 4° C./sec., it is possible to satisfactorily secure a time for removing an oxide film of the solder by the reduction action of the activator. This can further enhance the wettability of the solder. A heating start temperature is generally, but not particularly limited to, an ordinary temperature.

Here, the second thermosetting resin composition 12 contains at least one of the di- or higher functional oxetane compound or the benzoxazine compound having two or more oxazine rings. This is divided into three cases. That is, a first case is a case where the second thermosetting resin composition 12 contains the oxetane compound but does not contain the benzoxazine compound. A second case is a case where the second thermosetting resin composition 12 does not contain the oxetane compound but contains the benzoxazine compound. A third case is a case where the second thermosetting resin composition 12 contains both the oxetane compound and the benzoxazine compound.

In the first case, when heating is performed for the soldering, the oxetane compound reduces the curing speed of the second thermosetting resin composition 12 to be lower than the speed at which the solder melts.

In the second case, when heating is performed for the soldering, the benzoxazine compound increases the curing start temperature of the second thermosetting resin composition 12. This does not necessarily mean that the curing start temperature of the second thermosetting resin composition 12 is higher than the melting point of the solder, but this means that the curing start temperature of the second thermosetting resin composition 12 is not too low as compared to the melting point of the solder. The difference between the melting point of the solder and the curing start temperature of the second thermosetting resin composition 12 varies in accordance with an extent to which the curing reaction of the second thermosetting resin composition 12 proceeds, but the difference is, as a rough reference, preferably smaller than or equal to 40° C. when the melting point of the solder is high and the curing start temperature of the second thermosetting resin composition 12 is low.

In the third case, as a synergetic effect of the first and the second cases, the curing speed of the second thermosetting resin composition 12 decreases, and the curing start temperature increases.

In each of the first to third cases, it is possible to reduce curing of the second thermosetting resin composition 12 before the solder of the second solder bumps 8 is melted during the soldering.

More specifically, in FIG. 8B, each second solder bump 8 is melted while the second solder bump 8 pushes the second thermosetting resin composition 12 in liquid form to the periphery of the second pad 22, and each second solder bump 8 comes into contact with the second pad 22. Then, the second thermosetting resin composition 12 starts curing, thereby forming the second resin part 52. The solder melded and in contact with the second pad 22 is cured through subsequent cooling, thereby forming the second solder bonding part 42.

Moreover, in FIG. 9B, each second solder bump 8 is melted while pushing, to the periphery of the second pad 22, the thermosetting sheet 100 which is started to melt, and each second solder bump 8 comes into contact with the second pad 22. Then, the thermosetting sheet 100 melted starts curing, thereby forming the second resin part 52. The solder melded and in contact with the second pad 22 is cured through subsequent cooling, thereby forming the second solder bonding part 42.

Moreover, in FIG. 10B, each second solder bump 8 which is in contact with the second pad 22 is melted by being heated and curs through subsequent cooling, thereby forming the second solder bonding part 42. The second thermosetting resin composition 12 disposed in the periphery of each second pad 22 starts curing while being in contact with the periphery of the second solder bonding part 42 which is melted by being heated and is in the course of formation, and thereby, the second resin part 52 is formed.

In each of the first to third cases, the second thermosetting resin composition 12 preferably further contains a di- or higher functional epoxy compound. This enables the formation of an uncured portion of the second thermosetting resin composition 12 to eventually be reduced and enables the strength of the second resin part 52 serving as the cured product of the second thermosetting resin composition 12 to be increased.

After completion of the reflow soldering, the semiconductor mounted article 3 as shown in FIG. 7 can be obtained.

Preferably, neither the activator nor the thixotropy-imparting agent is substantially left in the second resin part 52. However, small amounts of the activator and the thixotropy-imparting agent may be left as long as the amounts do not impair reliability. Accordingly, it is unnecessary to remove the activator and the thixotropy-imparting agent through washing.

### EXAMPLES

The present invention will be specifically described with reference to examples below.

[Thermosetting Resin Composition]

As components included in the thermosetting resin composition, the following components were used.

(Thermosetting Resin)

<Main Agent>
Oxetane compound represented by formula (O1) (“ETERNACOLL OXBP” (abbreviated as OXBP) manufactured by Ube Industries, Ltd.)
Oxetane compound represented by formula (O2) (“ETERNACOLL OXIPA” (abbreviated as OXIPA) manufactured by Ube Industries, Ltd.)
Oxetane compound represented by formula (O3) (“OXT-121” (abbreviated as XDO) manufactured by Toagosei Co., Ltd.)
Oxetane compound represented by formula (O4) (“OXT-221” (abbreviated as DOX) manufactured by Toagosei Co., Ltd.)
Epoxy compound (“EPIKOTE 806” (bisphenol F-based epoxy resin) manufactured by Mitsubishi Chemical Corporation)

<Curing Agent>
Benzoxazine compound represented by formula (B1) (“Pd type” manufactured by SHIKOKU CHEMICALS CORPORATION)
Benzoxazine compound represented by formula (B2) ((bisphenol F-based)“BF-BXZ” manufactured by Konishi Chemical Ind. Co., Ltd.)
Benzoxazine compound represented by formula (B3) ((bisphenol S-based) “BS-BXZ”) manufactured by Konishi Chemical Ind. Co., Ltd.)

(Curing Accelerator)
2-phenyl-4,5-dihydroxy methylimidazole (“2PHZ-PW” manufactured by SHIKOKU CHEMICALS CORPORATION)

(Activator)
Glutaric acid
Triethanolamine

(Thixotropy-Imparting Agent)
Amide-based wax (“ITOHWAX J-420” (N-hydroxyethyl-12-hydroxystearylamide) manufactured by Itoh Oil Chemicals Co., Ltd.)

### Examples 1 to 20

The thermosetting resin composition in each of Examples 1 to 20 was produced as described below. The content of each component is shown in Table 1.

A thixotropy-imparting agent, an oxetane compound, and an epoxy compound (not used in Example 10) were blended together and heated to melt the thixotropy-imparting agent, thereby obtaining a first mixture.

With the first mixture, an activator and a curing agent were blended to obtain a mixture, which was kneaded with a planetary mixer, thereby obtaining a liquid thermosetting resin composition at an ordinary temperature. Note that the activator and the curing agent used were those sieved through a 120-mesh screen.

### Comparative Example 1

The thermosetting resin composition in Comparative Example 1 was produced as described below. The content of each component is shown in Table 1.

A thixotropy-imparting agent and an epoxy compound were blended together and heated to melt the thixotropy-imparting agent, thereby obtaining a first mixture.

With the first mixture, an activator and a curing accelerator were blended to obtain a mixture, which was kneaded with a planetary mixer, thereby obtaining a liquid thermosetting resin composition at an ordinary temperature. Note that the activator and the curing accelerator used were those sieved through a 120-mesh screen.

(Test for Checking Effect of Flux)

The thermosetting resin composition thus obtained was tested to check the effect of flux according to the following procedure.

1. A substrate which is rectangular (2 cm×5 cm) and which has a surface provided with round-shaped lands (having a diameter of 2 mm) made of copper was prepared.

2. A thermosetting resin composition was applied to cover the lands on the substrate.

3. Three solder balls (diameter 0.76 mm) which are spherical were placed on the thermosetting resin composition on the lands. The solder balls are made of Sn—Ag—Cu-based solder. More specifically, a solder alloy composition of each solder ball is SAC305, that is, each solder ball contains 96.5% by mass Sn, 3.0% by mass Ag, and 0.5% by mass Cu.

4. The substrate set to a temperature higher than the liquidus temperature of the solder balls by 50° C. was heated with a hot plate for about 30 seconds and the state of the solder balls were observed.

The solder balls were evaluated as “A”, “B”, “C” in order from the best effect of flux.

“A”: The three solder balls were melted to be aggregated and further leaked to spread on the lands.

“B”: The three solder balls were melted but were not satisfactorily aggregated, or the three solder balls were melted to be aggregated but insufficiently leaked to spread on the lands.

“C”: The three solder balls were not melted, were not aggregated, and did not leak to spread on the lands.

(Degree of Curing of Resin)

The solder balls were evaluated as “A”, “B”, “C” in order from the best degree of curing of the resin after the test for checking the effect of flux.

“A”: The resin is satisfactorily cured.

“B”: The resin has few uncured portions.

“C”: The resin has uncured portions and thus is tacky.

TABLE 1

| | | | | | Example | | | | | | | | | | |
|---|---|---|---|---|---|---|---|---|---|---|---|---|---|---|---|
| | | | | | 1 | 2 | 3 | 4 | 5 | 6 | 7 | 8 | 9 | 10 | 11 |
| Thermosetting | Main | Oxetane | OXBP | part by mass | 0 | 0 | 75 | 0 | 0 | 75 | 0 | 0 | 75 | 0 | 0 |
| Resin | Agent | Compound | (Formula(O1)) | | | | | | | | | | | | |
| | | | OXIPA | part by mass | 0 | 75 | 0 | 0 | 75 | 0 | 0 | 75 | 0 | 0 | 0 |
| | | | (Formula (O2)) | | | | | | | | | | | | |
| | | | XDO | part by mass | 75 | 0 | 0 | 75 | 0 | 0 | 75 | 0 | 0 | 100 | 50 |
| | | | (Formula (O3)) | | | | | | | | | | | | |
| | | | DOX | part by mass | 0 | 0 | 0 | 0 | 0 | 0 | 0 | 0 | 0 | 0 | 0 |
| | | | (Formula (O4)) | | | | | | | | | | | | |
| | | Epoxy Compound | EPIROTE | part by mass | 25 | 25 | 25 | 25 | 25 | 25 | 25 | 25 | 25 | 0 | 50 |
| | | | 806 | | | | | | | | | | | | |
| | Curing | Benzo Oxazine | P-d | part by mass | 0 | 0 | 0 | 25 | 25 | 25 | 0 | 0 | 0 | 0 | 0 |
| | Agent | Compound | (Formula (B1)) | | | | | | | | | | | | |
| | | | BF-BXZ | part by mass | 25 | 25 | 25 | 0 | 0 | 0 | 0 | 0 | 0 | 25 | 25 |
| | | | (Formula (B2)) | | | | | | | | | | | | |
| | | | BS-BXZ | part by mass | 0 | 0 | 0 | 0 | 0 | 0 | 25 | 25 | 25 | 0 | 0 |
| | | | (Formula (B3)) | | | | | | | | | | | | |

| Curing | 2PHZ-PW | | part by mass | 0 | 0 | 0 | 0 | 0 | 0 | 0 | 0 | 0 | 0 | 0 |
|---|---|---|---|---|---|---|---|---|---|---|---|---|---|---|
| Accelerator | | | | | | | | | | | | | | |
| Activator | Glutaric Acid | | part by mass | 10 | 10 | 10 | 10 | 10 | 10 | 10 | 10 | 10 | 10 | 10 |
| | Triethanolamine | | part by mass | 20 | 20 | 20 | 20 | 20 | 20 | 20 | 20 | 20 | 20 | 20 |
| Thixotropy- | Amide-Based Wax | ITOHWAX J-420 | part by mass | 5 | 5 | 5 | 5 | 5 | 5 | 5 | 5 | 5 | 5 | 5 |
| Imparting Agent | | | | | | | | | | | | | | |

| | | | | | | | | | | | | |
|---|---|---|---|---|---|---|---|---|---|---|---|---|
| Evaluation | Test for Checking Effect of Flux | A | A | A | A | A | A | A | A | A | A | A |
| Item | Degree of Curing of Resin | A | A | A | A | A | A | A | A | A | A | A |

| | | | | | | | | | | | | | | Comp. |
|---|---|---|---|---|---|---|---|---|---|---|---|---|---|---|
| | | | | | Example | | | | | | | | | Ex. |
| | | | | | 12 | 13 | 14 | 15 | 16 | 17 | 18 | 19 | 20 | 1 |
| Thermosetting | Main | Oxetane | OXBP | part by mass | 0 | 0 | 0 | 0 | 0 | 0 | 0 | 0 | 0 | 0 |
| Resin | Agent | Compound | (Formula(O1)) | | | | | | | | | | | |
| | | | OXIPA | part by mass | 0 | 0 | 0 | 0 | 0 | 0 | 0 | 0 | 0 | 0 |
| | | | (Formula (O2)) | | | | | | | | | | | |
| | | | XDO | part by mass | 45 | 75 | 75 | 75 | 75 | 75 | 0 | 0 | 0 | 0 |
| | | | (Formula (O3)) | | | | | | | | | | | |
| | | | DOX | part by mass | 0 | 0 | 0 | 0 | 0 | 0 | 75 | 75 | 75 | 0 |
| | | | (Formula (O4)) | | | | | | | | | | | |
| | | Epoxy Compound | EPIROTE | part by mass | 55 | 25 | 25 | 25 | 25 | 25 | 25 | 25 | 25 | 100 |
| | | | 806 | | | | | | | | | | | |
| | Curing | Benzo Oxazine | P-d | part by mass | 0 | 0 | 0 | 0 | 0 | 0 | 0 | 25 | 0 | 0 |
| | Agent | Compound | (Formula (B1)) | | | | | | | | | | | |
| | | | BF-BXZ | part by mass | 25 | 40 | 10 | 5 | 45 | 25 | 25 | 0 | 0 | 0 |
| | | | (Formula (B2)) | | | | | | | | | | | |
| | | | BS-BXZ | part by mass | 0 | 0 | 0 | 0 | 0 | 0 | 0 | 0 | 25 | 0 |
| | | | (Formula (B3)) | | | | | | | | | | | |

| Curing | 2PHZ-PW | | part by mass | 0 | 0 | 0 | 0 | 0 | 0 | 0 | 0 | 0 | 15 |
|---|---|---|---|---|---|---|---|---|---|---|---|---|---|
| Accelerator | | | | | | | | | | | | | |
| Activator | Glutaric Acid | | part by mass | 10 | 10 | 10 | 10 | 10 | 10 | 10 | 10 | 10 | 10 |
| | Triethanolamine | | part by mass | 20 | 20 | 20 | 20 | 20 | 20 | 20 | 20 | 20 | 20 |
| Thixotropy- | Amide-Based Wax | ITOHWAX J-420 | part by mass | 5 | 5 | 5 | 5 | 5 | 5 | 5 | 5 | 5 | 5 |
| Imparting Agent | | | | | | | | | | | | | |

| | | | | | | | | | | | |
|---|---|---|---|---|---|---|---|---|---|---|---|
| Evaluation | Test for Checking Effect of Flux | B | A | A | A | B | A | A | A | A | C |
| Item | Degree of Curing of Resin | A | A | A | B | A | A | A | A | A | A |

As can be seen from Table 1, in Comparative Example 1, which adopted neither the oxetane compound nor the benzoxazine compound and which adopted a curing accelerator, the solder balls were not aggregable. This is probably because the curing accelerator accelerates the curing reaction of the thermosetting resin, which makes it difficult to elicit the effect of flux, so that an oxide film on the surface of the solder ball is not satisfactorily removed.

In contrast, in Examples 1 to 20, which adopted the oxetane compound and the benzoxazine compound and which did not adopt the curing accelerator, the solder balls were aggregable. This is probably because the oxetane compound and the benzoxazine compound suppress the curing reaction of the thermosetting resin from proceeding, and the thermosetting resin composition does not inhibit the melted solder balls from leaking to spread on the lands.

From the comparison of Examples 1, 10, 11 to Example 12, it was found that the oxetane compound is preferably greater than or equal to 50% by mass of the total mass of the main agent. That is, in Examples 1, 10, and 11, deceleration of the curing reaction due to the oxetane compound is dominant, and aggregation of the melted solder balls is less likely to be inhibited. In contrast, in Example 12, acceleration of the curing reaction by the epoxy compound is slightly dominant, which slightly inhibits the aggregation of the melted solder balls.

From an evaluation result of Example 15, it was found that when the benzoxazine compound is less than or equal to 10 parts by mass with respect to 100 parts by mass of the main agent, few uncured portions were formed in the cured product of the thermosetting resin.

From an evaluation result of Example 16, it was found that when the benzoxazine compound is greater than 40 parts by mass with respect to 100 parts by mass of the main agent, curing of the thermosetting resin is slightly accelerated, which slightly inhibits the aggregation of the melted solder balls.

### REFERENCE SIGNS LIST

2 Semiconductor Component
3 Semiconductor Mounted Article
5 Semiconductor Package
6 First Solder Bump
8 Second Solder Bump
9 Gap
11 First Thermosetting Resin Composition
12 Second Thermosetting Resin Composition
21 First Pad
22 Second Pad
31 First Substrate
32 Second Substrate
41 First Solder Bonding Part
42 Second Solder Bonding Part
51 First Resin Part
52 Second Resin Part
61 Land

1. A thermosetting resin composition, comprising:
a thermosetting resin;
an activator; and
a thixotropy-imparting agent,
the thermosetting resin containing a main agent and a curing agent,
the main agent containing an oxetane compound which is a di- or higher functional oxetane compound.

2. The thermosetting resin composition of claim 1, wherein
the oxetane compound is one or more types of compounds selected from the group consisting of formulae (O1) to (O4) below: 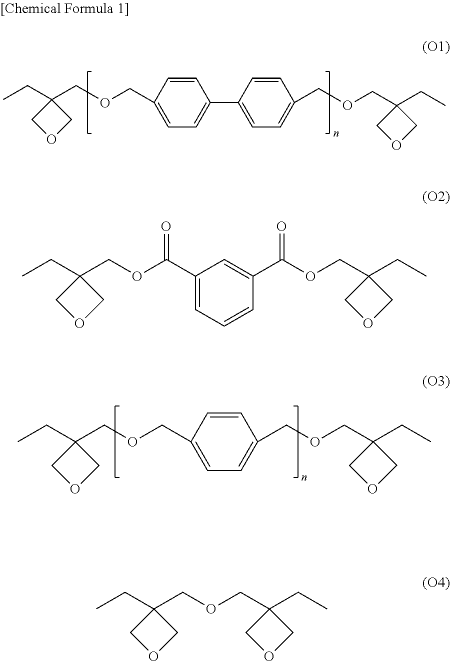
(In each of the formulae (O1) and (O3), n is an integer of any of 1 to 3.)

3. The thermosetting resin composition of claim 1, wherein
the oxetane compound is 50% by mass or more relative to a total mass of the main agent.

4. The thermosetting resin composition of claim 1, wherein
the curing agent contains a benzoxazine compound including two or more oxazine rings.

5. The thermosetting resin composition of claim 1, wherein
the main agent contains a di- or higher functional epoxy compound.

6. The thermosetting resin composition of claim 1, wherein
the activator contains one or more types of compounds selected from the group consisting of a glutaric acid and triethanolamine.

7. The thermosetting resin composition of claim 1, wherein
the thixotropy-imparting agent contains amide-based wax.

8. A thermosetting resin composition, comprising:
a thermosetting resin;
an activator; and
a thixotropy-imparting agent,
the thermosetting resin containing a main agent and a curing agent,
the curing agent containing a benzoxazine compound having two or more benzoxazine rings.

9. The thermosetting resin composition of claim 8, wherein
the benzoxazine compound is one or more types of compounds selected from the group consisting of formulae (B1) to (B3) below:

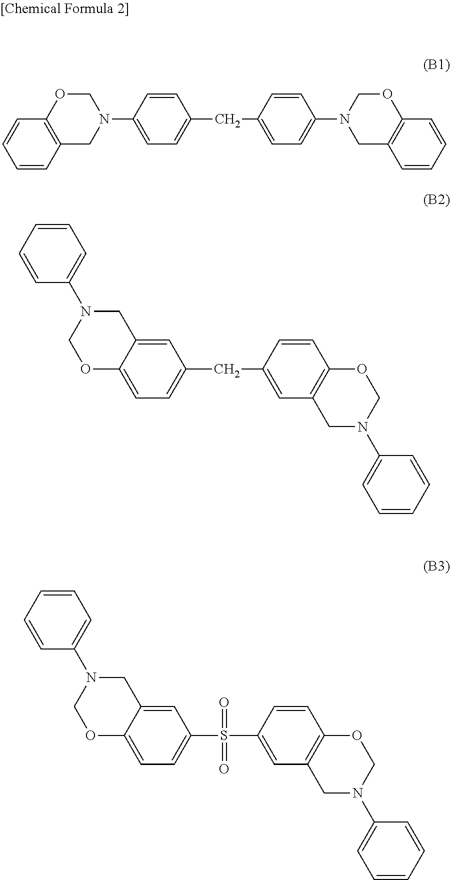 [SMILES: c1ccc2c(c1)CN(c1ccc(Cc3ccc(N4COc5ccccc5C4)cc3)cc1)CO2 ; c1ccc(N2COc3ccc(Cc4ccc5c(c4)CN(c4ccccc4)CO5)cc3C2)cc1 ; O=S(=O)(c1ccc2c(c1)CN(c1ccccc1)CO2)c1ccc2c(c1)CN(c1ccccc1)CO2]

10. The thermosetting resin composition of claim 8, wherein
the benzoxazine compound is greater than or equal to 10 parts by mass and less than or equal to 40 parts by mass with respect to 100 parts by mass of the main agent.

11. The thermosetting resin composition of claim 8, wherein
the main agent contains a di- or higher functional oxetane compound.

12. The thermosetting resin composition of claim 8, wherein
the main agent contains a di- or higher functional epoxy compound.

13. The thermosetting resin composition of claim 8, wherein
the activator contains one or more types of compounds selected from the group consisting of a glutaric acid and triethanolamine.

14. The thermosetting resin composition of claim 8, wherein
the thixotropy-imparting agent contains amide-based wax.

15. A thermosetting sheet formed from a semi-cured product of the thermosetting resin composition of claim 1.

16. A semiconductor component, comprising:
a semiconductor package;
a first substrate having a first surface and a first pad formed on the first surface;
a first solder bonding part which electrically connects the semiconductor package to the first pad; and
a first resin part in contact with the first solder bonding part,
the first resin part being formed from a cured product of a first thermosetting resin composition containing at least one of a di- or higher functional oxetane compound or a benzoxazine compound having two or more oxazine rings.

17. The semiconductor component of claim 16, wherein
the first solder bonding part has a melting point higher than or equal to 100° C. and lower than or equal to 240° C.

18. The semiconductor component of claim 16 or 17, wherein
the first solder bonding part is made of Sn—Ag—Cu-based solder or Sn—Bi-based solder.

19. The semiconductor component of claim 16, wherein
the first thermosetting resin composition further contains a di- or higher functional epoxy compound.

20. A semiconductor mounted article, comprising:
a semiconductor package,
a first substrate having a first surface and a second surface on an opposite side from the first surface, the first substrate having a first pad formed on the first surface and a land formed on the second surface;
a first solder bonding part which electrically connects the semiconductor package to the first pad;
a first resin part in contact with the first solder bonding part;
a second substrate having a first surface and a second pad formed on the first surface;
a second solder bonding part which electrically connects the land to the second pad; and
a second resin part in contact with the second solder bonding part,
the first resin part being formed from a cured product of a first thermosetting resin composition containing at least one of a di- or higher functional oxetane compound or a benzoxazine compound having two or more oxazine rings,
the second resin part being formed from a cured product of a second thermosetting resin composition containing at least one of a di- or higher functional oxetane compound or a benzoxazine compound having two or more oxazine rings.

21. The semiconductor mounted article of claim 20, wherein
at least one of the first solder bonding part or the second solder bonding part has a melting point higher than or equal to 100° C. and lower than or equal to 240° C.

22. The semiconductor mounted article of claim 20, wherein
at least one of the first solder bonding part or the second solder bonding part is made of Sn—Ag—Cu-based solder or Sn—Bi-based solder.

23. The semiconductor mounted article of claim 20, wherein
at least one of the first thermosetting resin composition or the second thermosetting resin composition further contains a di- or higher functional epoxy compound.

24.-31. (canceled)
